(19) United States
(12) Patent Application Publication
(10) Pub. No.: US 2024/0161824 A1
(43) Pub. Date: May 16, 2024

(54) MEMORY DEVICE AND OPERATING METHOD OF THEREOF

(71) Applicant: Samsung Electronics Co., Ltd., Suwon-si (KR)

(72) Inventors: Kyungmin LEE, Suwon-si (KR); Youngkeol KIM, Suwon-si (KR); Daeshik KIM, Suwon-si (KR)

(73) Assignee: Samsung Electronics Co., Ltd., Suwon-si (KR)

(21) Appl. No.: 18/503,719

(22) Filed: Nov. 7, 2023

(30) Foreign Application Priority Data
Nov. 15, 2022 (KR) 10-2022-0152741

(51) Int. Cl. G11C 13/00

(52) U.S. Cl. CPC G11C 13/0064; G11C 13/004; G11C 13/0069

(57) ABSTRACT

A memory device including a memory cell including a variable resistance element, a controller configured to generate a control signal based on whether the memory device performs a read operation or a verify read operation, a reference cell including a reference resistance circuit configured to have different resistance values depending on the control signal, and a sense amplifier configured to sense a difference between a read voltage value applied from the memory cell and a reference voltage value applied from the reference resistance circuit may be provided.

### CROSS-REFERENCE TO RELATED APPLICATION

This application is based on and claims priority under 35 U.S.C. § 119 to Korean Patent Application No. 10-2022-0152741, filed on Nov. 15, 2022, in the Korean Intellectual Property Office, the disclosure of which is incorporated by reference herein in its entirety.

### BACKGROUND

The inventive concepts relate to memory devices, and more particularly, to memory devices that is configured to perform a verify read operation while performing a write operation on data.

A resistive memory device may store data in a memory cell including a variable resistance element. When receiving a data write command from a memory controller, the resistive memory device may provide a write current or write voltage to a memory cell. Accordingly, because the resistance value of the variable resistance element included in the memory cell has a value corresponding to data to be written, data may be written into the resistive memory device.

To prevent data from being miswritten in the resistive memory device, the resistive memory device may perform a verify read operation to determine whether stored data values are correct. The verify read operation is an operation for guaranteeing reliability of data written in a memory cell. However, when the memory cell is in an abnormal state (e.g., an intermediate state or a read circuit failure state), it may not be possible to determine whether data has been miswritten in the memory cell even if the verify read operation is performed. Thus, it is necessary to develop a method that may more accurately verify whether or not data is entered incorrectly.

### SUMMARY

The inventive concepts provide memory devices capable of accurately verifying whether data is written incorrectly through a verify read operation.

According to an aspect of the inventive concepts, a memory device may include a memory cell including a variable resistance element, a controller configured to generate a control signal based on whether the memory device performs a read operation or a verify read operation, a reference cell including a reference resistance circuit configured to have different resistance values depending on the control signal, and a sense amplifier configured to sense a difference between a read voltage value applied from the memory cell and a reference voltage value applied from the reference resistance circuit.

According to another aspect of the inventive concepts, a method of operating a memory device for writing data into a memory cell including a variable resistance element may include receiving a write command for target data from a memory controller, generating and outputting a control signal for adjusting a resistance value of a reference resistance circuit based on the target data, writing the target data to the memory cell, and performing a verify read operation on the memory cell based on a read voltage value applied from the memory cell and a reference voltage value applied from the reference resistance circuit.

According to another aspect of the inventive concepts, a memory device may include a memory cell including a variable resistance element, a reference cell including a reference resistance circuit having a reference resistance value corresponding to a resistance value of the variable resistance element, a controller configured to generate a control signal based on whether the memory device performs a read operation or a verify read operation, a first current supply circuit including a first current source and configure to apply a read current to the memory cell based on the control signal, a second current supply circuit including a second current source and configured to apply a reference current to the reference resistance circuit based on the control signal, and a sense amplifier configured to sense a difference between a read voltage value applied from the memory cell and a reference voltage value applied from the reference resistance circuit.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram illustrating a memory system according to an example embodiment;

FIG. 2 is a block diagram illustrating a memory device according to an example embodiment;

FIG. 3 is a flowchart illustrating an operation performed when a memory device receives a write command, according to a comparative embodiment;

FIG. 4 is a graph illustrating distribution and change of resistance values of variable resistance elements included in memory cells of a memory device;

FIG. 5 is a circuit diagram illustrating a main configuration of a memory device according to an example embodiment;

FIG. 6 is a circuit diagram illustrating a reference resistance circuit of a memory device according to an example embodiment;

FIG. 7 is a diagram illustrating a distribution circuit that may be included in a reference resistance circuit of a memory device according to an example embodiment;

FIG. 8 is a table showing an example of input values and output values of the distribution circuit shown in FIG. 7;

FIGS. 9A and 9B are graphs illustrating a change in resistance value of a reference resistance circuit in a memory device according to an example embodiment;

FIG. 10 is a flowchart illustrating a method of operating a memory device according to an example embodiment;

FIG. 11 is a circuit diagram illustrating a main configuration of a memory device according to another example embodiment;

FIGS. 12A and 12B are graphs illustrating changes in distribution of resistance values of variable resistance elements in a memory device according to an example embodiment;

FIG. 13 is a block diagram illustrating a memory system including a memory device according to an example embodiment; and

FIG. 14 is a block diagram illustrating a system-on-chip including a memory device according to an example embodiment;

### DETAILED DESCRIPTION

Hereinafter, some example embodiments of the present disclosure will be described in detail with reference to the accompanying drawings.

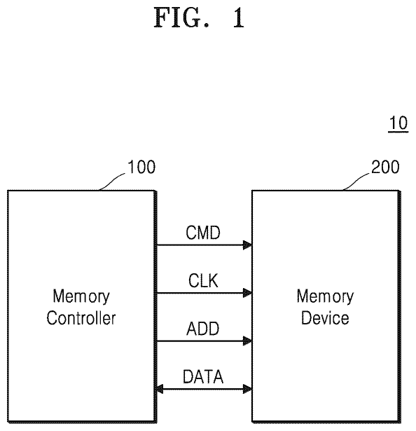

FIG. 1 is a block diagram illustrating a memory system according to an example embodiment.

Referring to FIG. 1, a memory system 10 according to an example embodiment may include a memory controller 100 and a memory device 200.

The memory controller 100 may transmit a command signal CMD, a clock signal CLK, and an address signal ADD to the memory device 200. Also, the memory controller 100 may transmit and receive data DATA to and from the memory device 200. The memory controller 100 may control the operation of the memory device 200.

In an example embodiment, the memory device 200 may be a magnetic random access memory (MRAM) including magnetic memory cells as a non-volatile memory, and may include spin transfer torque MRAM (STT-MRAM) cells. The STT-MRAM cell may include a selection transistor and a variable resistance device (e.g., a magnetic tunnel junction (MTJ)).

However, the inventive concepts are not limited thereto, and the memory device 200 may be any one of a phase change memory, a phase change memory and switch (PCMS), a resistive random access memory (RRAM), a ferroelectric memory, a spin-transfer torque random access memory (STT-RAM), a spin tunneling random access memory (STRAM), a magnetoresistive memory, a magnetic memory, and a semiconductor-oxide-nitride-oxide-semiconductor (SONOS).

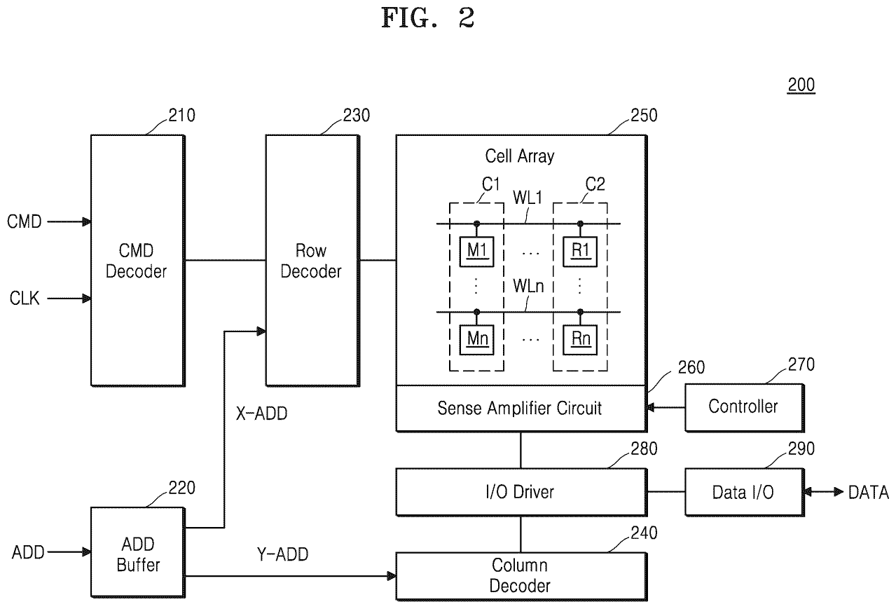

FIG. 2 is a block diagram illustrating a memory device according to an example embodiment.

Referring to FIG. 2, the memory device 200 includes a command decoder 210, an address buffer 220, a row decoder 230, a column decoder 240, a cell array 250, a sense amplifier circuit 260, a controller 270, an I/O driver 280, and a data I/O 290.

The command decoder 210 may perform a decoding operation based on the command signal CMD and the clock signal CLK received from the memory controller 100. The memory device 200 may be controlled to execute a command of the memory controller 100 after decoding by the command decoder 210 is completed.

The address buffer 220 may store the address signal ADD received from the memory controller 100. The address buffer 220 may transfer the row address X-ADD to the row decoder 230. The address buffer 220 may transfer the column address Y-ADD to the column decoder 240.

Each of the row decoder 230 and the column decoder 240 may include a number of switches. The row decoder 230 may be switched in response to the row address X-ADD to select a word line. The column decoder 240 may be switched in response to the column address Y-ADD to select a bit line.

The cell array 250 may include memory cells positioned at intersections of word lines and bit lines.

In an example embodiment, the memory cells may be STT-MRAM cells. The STT-MRAM cell may be a resistive memory cell having non-volatile characteristics, and the STT-MRAM cell may have a relatively large or small resistance value depending on written data.

The cell array 250 may include a plurality of memory cells M1 to Mn. Each of the plurality of memory cells M1 to Mn may include a variable resistance element (e.g., MTJ). The variable resistance element may have a resistance value corresponding to data stored in the memory cell.

The cell array 250 may include a plurality of reference cells R1 to Rn. In an example embodiment, the plurality of reference cells R1 to Rn may include reference resistance circuits configured to have different resistance values depending on control signals received from the controller 270. In addition, in another example embodiment, the plurality of reference cells R1 to Rn may include reference resistors having resistance values corresponding to resistance values of variable resistance elements included in the plurality of memory cells M1 to Mn.

The cell array 250 may include a first column C1 including the first to nth memory cells M1 to Mn and a second column C2 including the first to nth reference cells R1 to Rn (where n is an integer greater than 1). The cell array 250 may further include a plurality of columns including memory cells in addition to the first column C1.

The first to nth memory cells M1 to Mn included in the first column C1 may be mutually exclusively selected by a plurality of word lines WLs. In addition, the first to nth reference cells R1 to Rn included in the second column C2 may also be mutually exclusive selected by the plurality of word lines WLs. For example, the first memory cell M1 and the first reference cell R1 may be selected by an activated first word line WL1. In addition, the nth memory cell Mn and the nth reference cell Rn may be selected by an activated nth word line WLn.

A reference cell (e.g., R1) selected by the same word line as the memory cell (e.g., M1) may be used to read data stored in the memory cell (e.g., M1) and may be used to verify the memory cell (e.g., M1).

When data is read, the sense amplifier circuit 260 may supply read current to the memory cell (e.g., M1) and supply reference current to the reference cell (e.g., R1). Accordingly, the sense amplifying circuit 260 may receive a read voltage value corresponding to the stored data from the memory cell (e.g., M1), and may receive a reference voltage value, which is a criterion for determining the value of the stored data, from the reference cell (e.g., R1). The sense amplifier circuit 260 may sense and amplify a difference between the read voltage value and the reference voltage value, and output a digital level data signal. The sense amplifier circuit 260 may include a plurality of sense amplifiers.

The controller 270 may generate a control signal based on whether the memory device 200 performs a read operation or a verify read operation. In an example embodiment, the controller 270 may transfer the generated control signal to the reference resistance circuit to adjust the resistance value of the reference resistance circuit. In another example embodiment, the controller 270 may adjust the read current supplied to the memory cell and the reference current supplied to the reference cell when data is read through the generated control signal.

The I/O driver 280 may transfer the data signal output from the sense amplifier circuit 260 to the data I/O 290.

The data I/O 290 may output the received data to the memory controller 100.

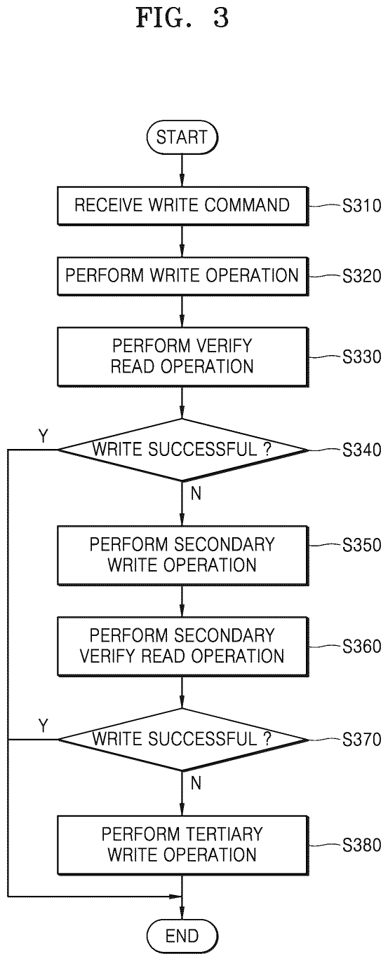

FIG. 3 is a flowchart illustrating an operation performed when a memory device receives a write command, according to a comparative example embodiment.

Referring to FIG. 3, operations performed by the memory device according to the comparative example embodiment upon receiving a write command from the memory controller may be identified.

In operation S310, the memory device may receive a write command for target data from the memory controller.

In operation S320, the memory device may perform a write operation for writing target data in a memory cell.

The memory device may write data into the memory cell by supplying a write current corresponding to the target data to the memory cell so that a resistance value of a variable resistance element included in the memory cell has a value corresponding to the target data.

In operation S330, the memory device may perform a verify read operation to determine whether the target data is correctly written in the memory cell.

The verify read operation may be an operation of reading data written in a memory cell to verify whether data is correctly written in the memory cell after the memory device performs the write operation upon receiving a write command from the memory controller. In a comparative embodiment, the verify read operation may be performed in the same way as the read operation.

The memory device may supply a read current to the memory cell and a reference current to a reference cell. In this case, the read current value and the reference current value may be the same. Next, the memory device may read data written in the memory cell by sensing and amplifying the read voltage value received from the memory cell and the reference voltage value received from the reference cell.

In operation S340, the memory device may determine whether writing of the target data is successful.

When the data read in operation S330 is the same as the target data, the memory device may determine that writing of the target data has succeeded. When it is determined that writing of the target data is successful, an operation involved in receiving a writing command may be terminated.

Conversely, the memory device may determine that writing of the target data has failed when the data read in operation S330 is different from the target data. When it is determined that the writing of the target data has failed, it may move to operation S350.

In operation S350, the memory device may perform a secondary write operation for writing target data to the memory cell. The secondary write operation may be performed in the same manner as the write operation of operation S320.

In operation S360, the memory device may perform a secondary verify read operation to determine whether target data is correctly written in the memory cell. The secondary verify read operation may be performed in the same manner as the verification read operation of operation S330.

In operation S370, the memory device may determine again whether writing of the target data is successful.

When the data read in operation S360 is the same as the target data, the memory device may determine that writing of the target data has succeeded. When it is determined that writing of the target data is successful, an operation involved in receiving a writing command may be terminated.

Conversely, the memory device may determine that writing of the target data has failed when the data read in operation S330 is different from the target data. When it is determined that the writing of the target data has failed, it may move to operation S380.

In operation S380, the memory device may perform a tertiary write operation for writing target data to a memory cell. The tertiary write operation may be performed in the same manner as the write operation of operation S320 and the secondary write operation of operation S350.

After the tertiary write operation is performed, an additional verify read operation may not be performed, and an operation involved in receiving a writing command may be terminated.

FIG. 3 shows an example in which up to the tertiary write operation is performed when writing to target data fails, but the inventive concepts are not limited thereto, and unlike FIG. 3, only up to the secondary write operation may be performed, or fourth or higher write operations may be additionally performed.

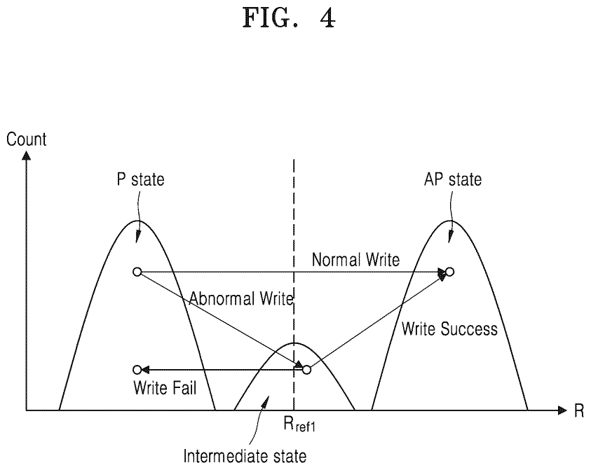

In the comparative example embodiment shown in FIG. 3, the memory device may perform a verify read operation based on a reference voltage value output as the same reference current as when performing a read operation is supplied to the reference cell including a reference resistance circuit, which has the same resistance value as when performing a read operation. That is, in a comparative embodiment, the memory device may determine a value of data written to a memory cell based on the same reference voltage value in the read operation and the verify read operation. In this case, even if the verify read operation is performed, it may not be possible to determine that data has been written incorrectly to the memory cell. This may be explained in more detail with reference to FIG. 4.

FIG. 4 is a graph illustrating distribution and change of resistance values of variable resistance elements included in memory cells of a memory device.

Referring to FIG. 4, the graph illustrating a distribution of resistance values R of variable resistance elements included in memory cells of the memory device may be checked. In the graph of FIG. 4, the horizontal axis represents the resistance value R of the variable resistance element included in the memory cell, and the vertical axis represents the number count of the variable resistance element having the corresponding resistance value.

The variable resistance element may be classified into three states based on a resistance value.

When the resistance value R of the variable resistance element is relatively small, the variable resistance element may be classified into a parallel (P) state. When the variable resistance element is in the P state, a memory cell including the variable resistance element may store a first value (e.g., logic 0).

When the resistance value R of the variable resistance element is relatively large, the variable resistance element may be classified as an anti-parallel (AP) state. When the variable resistance element is in the AP state, a memory cell including the variable resistance element may store a second value (e.g., logic 1).

When the resistance value R of the variable resistance element is intermediate between the resistance value in the P state and the resistance value in the AP state, the variable resistance element may be classified as an intermediate state. A variable resistance element may not maintain an intermediate state for a long time due to its physical characteristics. That is, when the variable resistance element is in an intermediate state, the state of the variable resistance element may be converted to the P state or the AP state within a short period of time.

An average value of a resistance value when the variable resistance element is in the P state and a resistance value when it is in the AP state may be set as a first reference resistance value R_{ref1}. In this case, the first reference resistance value R_{ref1} may be set to a resistance value of a reference resistor included in the reference cell. In a comparative embodiment, when the memory device performs the read operation and the verify read operation, the value of the data stored in the memory cell may be determined based on the first reference resistance value R_{ref1}.

The graph of FIG. 4 shows an example of state change of the variable resistance element when the memory device writes the second value into the memory cell in which the first value is stored.

When the second value is normally written into the memory cell in which the first value is stored, the state of the variable resistance element may be immediately converted from the P state to the AP state.

However, when the second value is abnormally written into the memory cell in which the first value is stored, the state of the variable resistance element may be converted from the P state to an intermediate state. A variable resistance element in an intermediate state may be randomly switched to the P state or the AP state. In this case, when the variable resistance element in the intermediate state is switched to the P state, data writing fails. Conversely, when the variable resistance element in the intermediate state is switched to the AP state, data writing is successful.

As described above with reference to the flowchart of FIG. 3, the memory device may immediately perform a verify read operation after performing a write operation. In this case, after data is abnormally written into the memory cell and the variable resistance element is in an intermediate state, a verify read operation may be performed before the memory cell is converted to the P state or the AP state.

In a comparative embodiment, when the second value is abnormally written to the memory cell in which the first value is stored and the variable resistance element has a resistance value greater than or equal to the first reference resistance value R_{ref1} in an intermediate state, when the memory device performs the verify read operation, it may be determined that data writing is successful. In this case, after the verify read operation is completed, when the variable resistance element in the intermediate state is converted to the AP state, no problem occurs. However, after the verify read operation is completed, when the variable resistance element in the intermediate state is converted to the P state, data miswriting may not be detected through the verify read operation, and thus reliability of the memory device deteriorates.

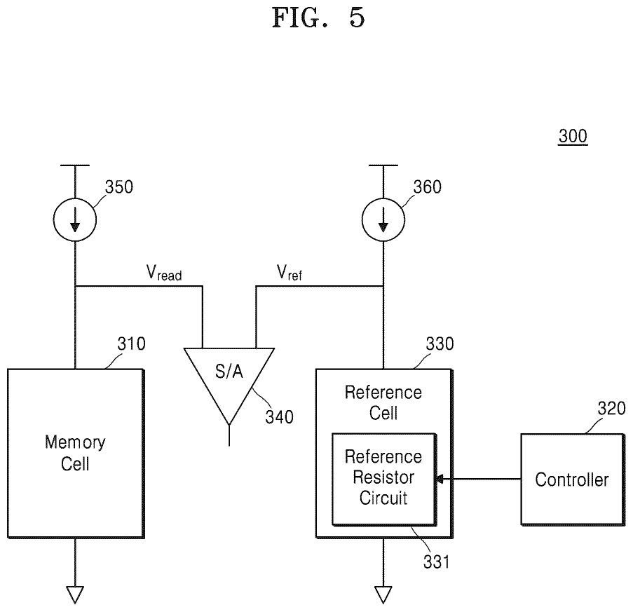

FIG. 5 is a circuit diagram illustrating a main configuration of a memory device according to an example embodiment.

Referring to FIG. 5, a memory device 300 according to an example embodiment may include a memory cell 310, a controller 320, a reference cell 330, and a sense amplifier 340. In addition, the memory device 300 may further include a first current source 350 and a second current source 360. In this case, the memory device 300 of FIG. 5 may be implemented in the memory device 200 of FIG. 1 or 2.

The memory cell 310 may store data. The memory cell 310 may include a variable resistance element.

The variable resistance element may be in a P state or an AP state depending on values of written data. For example, when the value of the data written in the memory cell 310 is the first value, the variable resistance element may be in the P state. Conversely, when the value of the data written in the memory cell 310 is the second value, the variable resistance element may be in the AP state. In addition, when an abnormal writing occurs in the memory cell 310, the variable resistance element may be temporarily in an intermediate state.

The controller 320 may generate a control signal based on whether the memory device 300 performs a read operation or a verify read operation.

In an example embodiment, when the memory device 300 performs a read operation, the controller 320 may generate a control signal that controls the resistance value of the reference resistance circuit 331 described below to be the same as a first reference resistance value R_{ref1}.

In an example embodiment, when the memory device 300 performs a read operation, the controller 320 may generate a control signal that controls the resistance value of the reference resistance circuit 331 described below to be different from the first reference resistance value R_{ref1}.

When the memory device 300 performs a verify read operation, the controller 320 may generate a control signal based on a target data value. The target data may be data intended to be written to a memory cell in a write operation corresponding to a verify read operation.

In an example embodiment, when the value of the target data is the first value, the controller 320 may generate a control signal that controls the resistance value of the reference resistance circuit 331 to be described below to have a second reference resistance value R_{ref2} less than a first reference resistance value R_{ref1}. In addition, when the value of the target data is the second value, the controller 320 may generate a control signal that controls the resistance value of the reference resistance circuit 331 to be described below to have a third reference resistance value R_{ref3} greater than the first reference resistance value R_{ref1}.

In this case, when the resistance value distribution of the variable resistance element is as shown in FIG. 4, the second reference resistance value R_{ref2} may be set to be greater than a maximum resistance value that the variable resistance element may have when it is in the P state and less than a minimum resistance value that the variable resistance element may have when it is in the intermediate state. In addition, when the resistance value distribution of the variable resistance element is as shown in FIG. 4, a third reference resistance value R_{ref3} may be set to be greater than a maximum resistance value that the variable resistance element may have when it is in the intermediate state and less than a minimum resistance value that the variable resistance element may have when it is in the AP state.

The reference cell 330 may include a reference resistance circuit 331. The reference resistance circuit 331 may be configured to have different resistance values depending on the control signal.

In an example embodiment, when the memory device 300 performs a read operation, the reference resistance circuit 331 may be configured to have the first reference resistance value R_{ref1} by a control signal.

In an example embodiment, when the memory device 300 performs a verify read operation, the reference resistance circuit 331 may be configured to have a resistance value different from the first reference resistance value R_{ref1} by a control signal. In this case, when the memory device 300 performs the verify read operation and the target data value is the first value, the reference resistance circuit 331 may be configured to have a second reference resistance value R_{ref2} lower than the first reference resistance value R_{ref1} by a control signal. In addition, when the memory device 300 performs the verify read operation and the target data value is the second value, the reference resistance circuit 331 may be configured to have the third reference resistance value R_{ref3} greater than the first reference resistance value R_{ef1} by a control signal.

The reference resistance circuit 331 may include a plurality of resistance elements and a plurality of switching elements. In this case, a resistance value of the reference resistance circuit 331 may change as a plurality of switching elements are turned on or off.

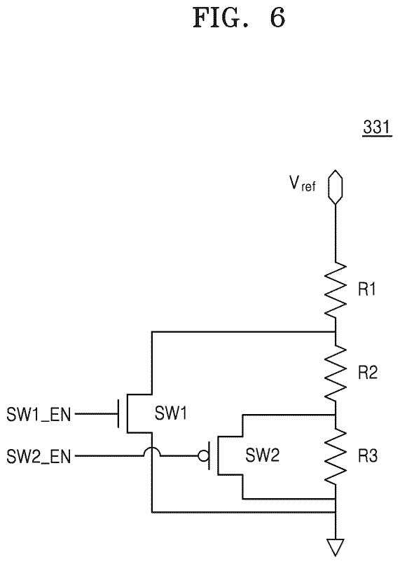

A detailed structure and operation of the reference resistance circuit 331 may be described with reference to FIGS. 6 to 8.

FIG. 6 is a circuit diagram illustrating a reference resistance circuit of a memory device according to an example embodiment.

Referring to FIG. 6, the reference resistance circuit 331 according to an example embodiment may include a first resistance element R1, a second resistance element R2, a third resistance element R3, a first switching element SW1, and a second switching element SW2.

The first resistance element R1 may be connected to the sense amplifier 340 of FIG. 5. The second resistance element R2 may be connected in series with the first resistance element R1. The third resistance element R3 may be connected in series with the second resistance element R2.

The first resistance element R1, the second resistance element R2, and the third resistance element R3 may be implemented with any one of poly silicon, metal line, MTJ, and the like.

In an example embodiment, a resistance value of each of the first resistance element R1, the second resistance element R2, and the third resistance element R3 may be set based on a distribution of resistance values of the variable resistance element.

For example, each resistance value of the first resistance element R1, the second resistance element R2, and the third resistance element R3 may be set based on the first reference resistance value R_{ref1}, the second reference resistance value R_{ref2}, and the third reference resistance value R_{ref3} based on the resistance value distribution of the variable resistance element.

The resistance value of the first resistance element R1 may be set equal to the second reference resistance value R_{ref2}.

A resistance value of the second resistance element R2 may be set equal to a difference between the first reference resistance value R_{ref1} and the second reference resistance value R_{ref2}. Accordingly, the sum of the resistance value of the first resistance element R1 and the resistance value of the second resistance element R2 may be equal to the first reference resistance value R_{ref1}.

A resistance value of the third resistance element R3 may be set equal to a difference between the third reference resistance value R_{ref3} and the first reference resistance value R_{ref1}. Accordingly, the sum of the resistance value of the first resistance element R1, the resistance value of the second resistance element R2, and the resistance value of the third resistance element R3 may be equal to the third reference resistance value R_{ref3}.

The first switching element SW1 may be connected in parallel with the second resistive element R2 and the third resistive element R3. The second switching element SW2 may be connected in parallel with the third resistance element R3.

The first switching element SW1 and the second switching element SW2 may be turned on or off by a control signal generated by the controller 320.

When the memory device 300 performs the read operation, the controller 320 may generate a control signal for controlling the first switching element SW1 to be turned off and the second switching element SW2 to be turned on. Accordingly, when the memory device 300 performs the read operation, the first switching element SW1 may be turned off and the second switching element SW2 may be turned on. In this case, because the current supplied to the variable resistor circuit 331 flows through the first resistance element R1, the second resistance element R2 and the second switching element SW2, the resistance value of the variable resistor circuit 331 may have a first reference resistance value R_{ref1} equal to the sum of the resistance values of the first resistance element R1 and the resistance value of the second resistance element R2.

When the memory device 300 performs the verify read operation, the controller 320 may control both the first switching element SW1 and the second switching element SW2 to be turned on or both the first switching element SW1 and the second switching element SW2 to be turned off.

For example, when the value of the target data is the first value when the memory device 300 performs the verify read operation, the controller 320 may generate a control signal for controlling both the first switching element SW1 and the second switching element SW2 to be turned on. Accordingly, when the value of the target data is the first value during the verify read operation, both the first switching element SW1 and the second switching element SW2 may be turned on. In this case, because the current supplied to the variable resistor circuit 331 flows through the first resistance element R1 and the first switching element SW1, the resistance value of the variable resistor circuit 331 may have the same second reference resistance value R_{ref2} as the resistance value of the first resistance element R1.

In addition, when the memory device 300 performs the verify read operation and the value of the target data is the second value, the controller 320 may generate a control signal for controlling both the first switching element SW1 and the second switching element SW2 to be turned off. Accordingly, when the value of the target data is the second value during the verify read operation, both the first switching element SW1 and the second switching element SW2 may be turned off. In this case, because the current supplied to the variable resistor circuit 331 flows through the first resistance element R1, the second resistance element R2, and the third resistance element R3, the resistance value of the variable resistor circuit 331 may have the third reference resistance value R_{ref3} equal to the sum of the resistance value of the first resistance element R1, the resistance value of the second resistance element R2, and the resistance value of the third resistance element R3.

The first switching element SW1 may be turned on or off based on a first switching enable signal SW1_EN. In an example embodiment, the first switching element SW1 may be NMOS. In this case, when the value of the first switching enable signal SW1_EN is logic 1, the first switching element SW1 may be turned on. Conversely, when the value of the first switching enable signal SW1_EN is logic 0, the first switching element SW1 may be turned off.

The second switching element SW2 may be turned on or off based on a second switching enable signal SW2_EN. In an example embodiment, the second switching element SW2 may be a PMOS. In this case, when the value of the second switching enable signal SW2_EN is logic 0, the second switching element SW2 may be turned on. Conversely, when the value of the second switching enable signal SW2_EN is logic 1, the second switching element SW2 may be turned off.

The first switching enable signal SW1_EN and the second switching enable signal SW2_EN may be included in control signals received from the controller 320.

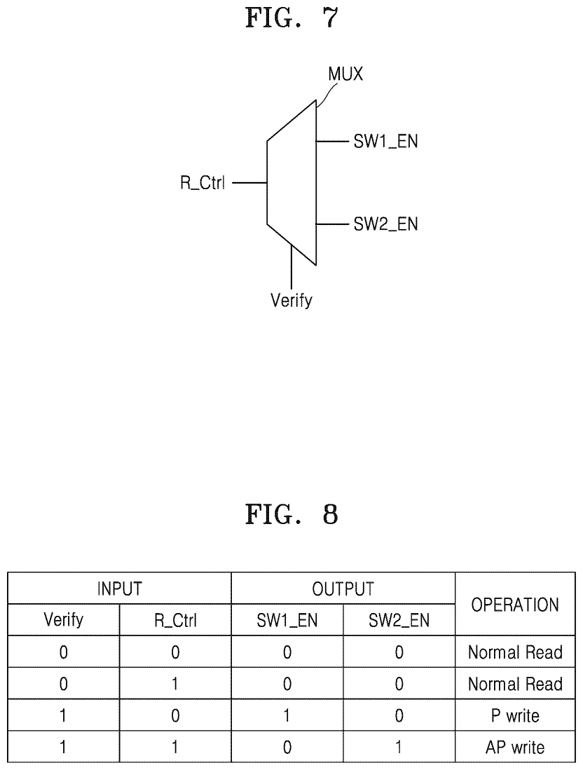

In another example, the reference resistance circuit 331 may further include a distribution circuit, and the first switching enable signal SW1_EN and the second switching enable signal SW2_EN may be generated by the distribution circuit based on the control signal. An example embodiment of the distribution circuit may be confirmed through FIG. 7.

FIG. 7 is a diagram illustrating a distribution circuit that may be included in a reference resistance circuit of a memory device according to an example embodiment.

Referring to FIG. 7, an example of a distribution circuit MUX that may be included in the reference resistance circuit 331 of the memory device 300 according to an example embodiment may be checked.

The distribution circuit MUX may receive the resistance value control signal R_Ctrl and a verification signal Verify as input values, and output the first switching enable signal SW1_EN and the second switching enable signal SW2_EN as output values. The resistance value control signal R_Ctrl and the verification signal verify may be included in the control signal received from the controller 320.

Here, the verification signal Verify may be a signal indicating which operation among the read operation and the verify read operation is performed by the memory device 300. Also, the resistance value control signal R_Ctrl may be a signal indicating an increase or decrease in the resistance value of the reference resistance circuit 331.

The first switching enable signal SW1_EN generated by the distribution circuit MUX may be output to the first switching element SW1, and the second switching enable signal SW2_EN may be output to the second switching element SW2.

In this case, a relationship between values of the resistance value control signal R_Ctrl and the verification signal Verify input to the distribution circuit MUX and the values of the first switching enable signal SW1_EN and the second switching enable signal SW2_EN output from the distribution circuit MUX may be as shown in FIG. 8.

FIG. 8 is a table showing an example of input values and output values of the distribution circuit shown in FIG. 7.

Referring to FIG. 8, a table showing values of signals input to the distribution circuit MUX and values of signals output from the distribution circuit MUX, and operations performed by the memory device 300 corresponding thereto may be checked.

When the operation performed by the memory device 300 is a read operation, the value of the verification signal Verify included in the control signal may be set to logic 0, and the value of the resistance value control signal R_Ctrl may be set to an arbitrary value of logic 0 or logic 1.

When the memory device 300 performs the read operation, the resistance value of the reference resistance circuit 331 must have the first reference resistance value R_{ref1}. Therefore, when the value of the verification signal Verify input to the distribution circuit MUX is logic 0, regardless of the value of the resistance value control signal R_Ctrl, the distribution circuit MUX may be configured to output a first switching enable signal SW1_EN having a logic 0 value and output a second switching enable signal SW2_EN having a logic 0 value. Accordingly, when the first switching element SW1 is turned off and the second switching element SW2 is turned on, the resistance value of the reference resistance circuit 331 may be the first reference resistance value R_{ref1}.

When the operation performed by the memory device 300 is a verify read operation and the value of the target data is the first value, the value of the verification signal Verify included in the control signal may be set to logic 1, and the value of the resistance value control signal R_Ctrl may be set to logic 0.

When the memory device 300 performs the verify read operation on data having a first target data value, the resistance value of the reference resistance circuit 331 must have the second reference resistance value R_{ref2}. Accordingly, when the value of the input verification signal Verify is logic 1 and the value of the resistance value control signal R_Ctrl is logic 0, the distribution circuit MUX may be configured to output a first switching enable signal SW1_EN having a logic 1 value and output a second switching enable signal SW2_EN having a logic 0 value. Accordingly, when the first switching element SW1 is turned on and the second switching element SW2 is turned on, the resistance value of the reference resistance circuit 331 may be the second reference resistance value R_{ref2}.

When the operation performed by the memory device 300 is a verify read operation and the value of the target data is the second value, the value of the verification signal Verify included in the control signal may be set to logic 1, and the value of the resistance value control signal R_Ctrl may be set to logic 1.

When the memory device 300 performs a verify read operation on data having the second target data value, the resistance value of the reference resistance circuit 331 must have the third reference resistor value R_{ref3}. Therefore, when the value of the input verification signal Verify is logic 1 and the value of the resistance value control signal R_Ctrl is logic 1, the distribution circuit MUX may be configured to output a first switching enable signal SW1_EN having a logic 0 value and output a second switching enable signal SW2_EN having a logic 1 value. Accordingly, when the first switching element SW1 is turned off and the second switching element SW2 is turned off, the resistance value of the reference resistance circuit 331 may be the third reference resistance value R_{ref3}.

Returning to FIG. 5, the sense amplifier 340 may detect a difference between the read voltage value V_{read} applied from the memory cell 310 and the reference voltage value V_{ref} applied from the reference resistance circuit 331. In an example embodiment, a voltage sense amplifier may be used as the sense amplifier 340, but the inventive concepts are not limited thereto, and a current sense amplifier may be used as the sense amplifier 340.

When the read voltage value V_{read} is less than the reference voltage value V_{ref}, the sense amplifier 340 may output a digital signal indicating that the value of the data written in the memory cell 310 is the first value. Conversely, when the read voltage value V_{read} is greater than the reference voltage value V_{ref}, the sense amplifier 340 may output a digital signal indicating that the value of the data written in the memory cell 310 is the second value.

The read voltage value V_{read} is a voltage value corresponding to the resistance value of the variable resistance element included in the memory cell 310, and may be output as the read current is applied to the variable resistance element by the first current source 350. The read voltage value V_{read} may be proportional to the read current value and the resistance value of the variable resistance element.

The reference voltage value V_{ref} is a voltage value corresponding to the resistance value of the reference resistance circuit 331 included in the reference cell 330, and may be output as the reference current is applied to the reference resistance circuit 331 by the second current source 360. The reference voltage value V_{ref} may be proportional to the reference current value and the resistance value of the reference resistance circuit 331.

In an example embodiment, the read current may have the same value as the reference current. Accordingly, the sense amplifier 340 may detect a difference between the resistance value of the variable resistance element and the resistance value of the reference resistance circuit 331 by sensing the difference between the read voltage value V rea d and the reference voltage value V_{ref}.

When the memory device 300 performs a read operation, the resistance value of the reference resistance circuit 331 may be set to the first reference resistance value R_{ref1} by a control signal.

When the memory device 300 performs a read operation, when the variable resistance element is in the P state, the resistance value of the variable resistance element is less than the first reference resistance value R_{ref1}, and thus the read voltage value V_{read} may be less than the reference voltage value V_{ref}. Accordingly, the sense amplifier 340 may output a digital signal indicating that the value of the data read from the memory cell 310 is the first value.

When the memory device 300 performs a read operation, when the variable resistance element is in the AP state, the resistance value of the variable resistance element is greater than the first reference resistance value R_{ef1}, and thus the read voltage value V_{read} may be greater than the reference voltage value V_{ref}. Accordingly, the sense amplifier 340 may output a digital signal indicating that the value of the data read from the memory cell 310 is the second value.

Because the memory device 300 performs a read operation after a certain amount of time elapses after data is written in the memory cell 310, when the memory device 300 performs a read operation, the variable resistance element cannot be in the intermediate state. Therefore, when the memory device 300 performs a read operation, data written in the memory cell 310 may be accurately sensed by setting the resistance value of the reference resistance circuit 331 to the first reference resistance value R_{ref1}.

When the value of the target data is the first value when the memory device 300 performs the verify read operation, the resistance value of the reference resistance circuit 331 may be set to the second reference resistance value R_{ref2} by the control signal.

When the memory device 300 performs the verify read operation, when the value of the target data is the first value and the variable resistance element is in the P state, the resistance value of the variable resistance element is less than the second reference resistance value R_{ref2}, and thus the read voltage value V_{read} may be less than the reference voltage value V_{ref}. Accordingly, the sense amplifier 340 may output a digital signal indicating that the value of the data read from the memory cell 310 is the first value. In this case, because the value of the target data is the same as the value of the data read through the verify read operation, the memory device 300 may determine that the write operation has been normally performed.

When the memory device 300 performs the verify read operation, when the value of the target data is the first value and the variable resistance element is in the AP state, the resistance value of the variable resistance element is greater than the second reference resistance value R_{ref2}, and thus the read voltage value V rea d may be greater than the reference voltage value V_{ref}. Accordingly, the sense amplifier 340 may output a digital signal indicating that the value of the data written in the memory cell 310 is the second value. In this case, because the value of the target data is different from the value of the data read through the verify read operation, the memory device 300 may determine that the write operation has been performed abnormally.

When the memory device 300 performs the verify read operation, when the value of the target data is the first value and the variable resistance element is in an intermediate state, the resistance value of the variable resistance element is greater than the second reference resistance value R_{ref2}, and thus the read voltage value V_{read} may be greater than the reference voltage value V_{ref}. Accordingly, the sense amplifier 340 may output a digital signal indicating that the value of the data written in the memory cell 310 is the second value. In this case, because the value of the target data is different from the value of the data read through the verification read operation, the memory device 300 may determine that the write operation has been abnormally performed.

In this way, by setting the resistance value of the reference resistance circuit 331 to the second reference resistance value R_{ref2} when the value of the target data is the first value, when the variable resistance element is in an intermediate state, it is determined that the write operation has been abnormally performed, and thus an erroneous write of data may be more accurately detected through the verify read operation.

In addition, when the memory device 300 performs the verify read operation and the value of the target data is the second value, the resistance value of the reference resistance circuit 331 may be set to the third reference resistance value R_{ref3} by the control signal.

When the memory device 300 performs the verify read operation, when the value of the target data is the second value and the variable resistance element is in the P state, the resistance value of the variable resistance element is smaller than the third reference resistance value R_{ref3}, and thus the read voltage value V_{read} may be smaller than the reference voltage value V_{ref}. Accordingly, the sense amplifier 340 may output a digital signal indicating that the value of the data read from the memory cell 310 is the first value. In this case, because the value of the target data is different from the value of the data read through the verify read operation, the memory device 300 may determine that the write operation has been performed abnormally.

When the memory device 300 performs the verify read operation, when the value of the target data is the second value and the variable resistance element is in the AP state, the resistance value of the variable resistance element is greater than the third reference resistance value R_{ref3}, and thus the read voltage value V_{read} may be greater than the reference voltage value V_{ref}. Accordingly, the sense amplifier 340 may output a digital signal indicating that the value of the data written in the memory cell 310 is the second value. In this case, because the value of the target data is the same as the value of the data read through the verify read operation, the memory device 300 may determine that the write operation has been normally performed.

When the memory device 300 performs the verify read operation, when the value of the target data is the second value and the variable resistance element is in an intermediate state, the resistance value of the variable resistance element is less than the third reference resistance value R_{ref3}, and thus the read voltage value V_{read} may be less than the reference voltage value V_{ref}. Accordingly, the sense amplifier 340 may output a digital signal indicating that the value of the data written in the memory cell 310 is the first value. In this case, because the value of the target data is different from the value of the data read through the verify read operation, the memory device 300 may determine that the write operation has been performed abnormally.

In this way, by setting the resistance value of the reference resistance circuit 331 to the third reference resistance value R_{ref3} when the value of the target data is the second value, when the variable resistance element is in an intermediate state, it is determined that the write operation has been abnormally performed, and thus an erroneous write of data may be more accurately detected through the verify read operation.

The first current source 350 may apply a read current to the memory cell 310. The second current source 360 may apply a reference current to the reference cell 330.

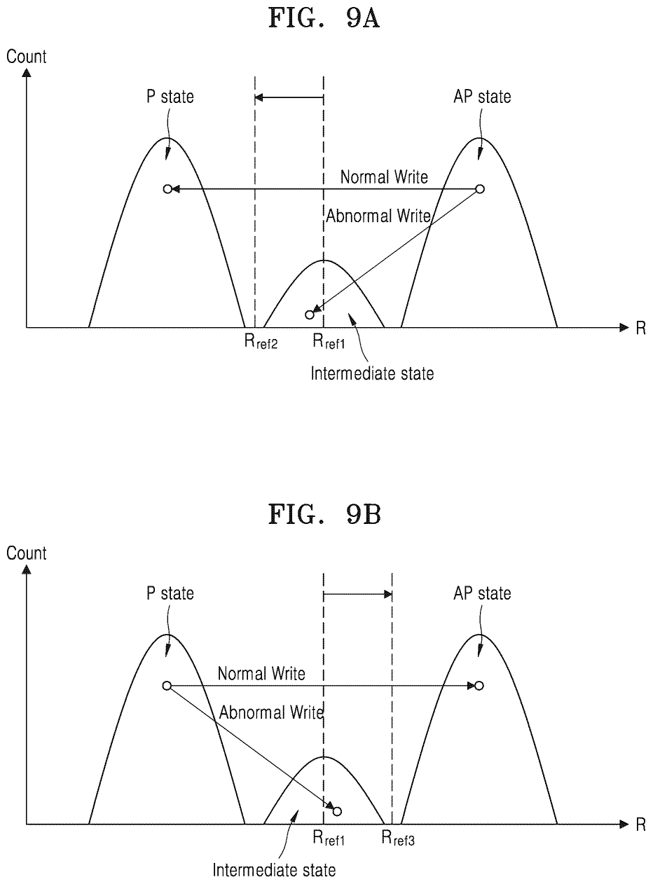

FIGS. 9A and 9B are graphs illustrating a change in resistance value of a reference resistance circuit in a memory device according to an example embodiment.

Referring to FIG. 9A, when the memory device 300 performs a verify read operation, a change in the resistance value of the reference resistance circuit 331 when the target data value is the first value may be checked. The resistance value of the reference resistance circuit 331 may change from the first reference resistance value R_{ref1} to the second reference resistance value R_{ref2} by a control signal.

The graph of FIG. 9A shows an example of a state change of the variable resistance element when the memory device 300 writes a first value into the memory cell 310 storing the second value.

When the first value is normally written into the memory cell 310 in which the second value is stored, the state of the variable resistance element may be immediately converted from the AP state to the P state.

However, when the first value is abnormally written into the memory cell 310 in which the second value is stored, the state of the variable resistance element may be converted from the AP state to an intermediate state. In this case, because the memory device 300 determines the value of the data written in the memory cell 310 based on the second reference resistance value R_{ref2}, the sense amplifier 340 may output a digital signal indicating that the value of the written data is the second value when the variable resistance element is in an intermediate state. In this case, because the value of the target data is different from the value of the data read through the verify read operation, the memory device 300 may determine that the write operation has been performed abnormally.

Accordingly, it is determined that the write operation has been performed abnormally regardless of which state of the variable resistance element is switched from the intermediate state to the P state or the AP state, and thus all data miswrites may be detected through the verify read operation.

Referring to FIG. 9B, when the memory device 300 performs the verify read operation, a change in the resistance value of the reference resistance circuit 331 when the target data value is the second value may be checked. The resistance value of the reference resistance circuit 331 may change from the first reference resistance value R_{ef1} to the third reference resistance value R_{ref3} by a control signal.

The graph of FIG. 9B shows an example of a state change of the variable resistance element when the memory device 300 writes the second value into the memory cell 310 in which the first value is stored.

When the second value is normally written into the memory cell 310 in which the first value is stored, the state of the variable resistance element may be immediately converted from the P state to the AP state.

However, when the second value is abnormally written into the memory cell 310 in which the first value is stored, the state of the variable resistance element may be converted from the P state to an intermediate state. In this case, because the memory device 300 determines the value of the data written in the memory cell 310 based on the third reference resistance value R_{ref3}, the sense amplifier 340 may output a digital signal indicating that the value of the written data is the first value when the variable resistance element is in an intermediate state. In this case, because the value of the target data is different from the value of the data read through the verify read operation, the memory device 300 may determine that the write operation has been performed abnormally.

Accordingly, it is determined that the write operation has been performed abnormally regardless of which state of the variable resistance element is switched from the intermediate state to the P state or the AP state, and thus all data miswrites may be detected through the verify read operation.

When the memory device 300 according to another example embodiment as described above with reference to FIGS. 5 and 9 is used, it is possible to accurately verify whether data is written incorrectly by adjusting the resistance value of the reference resistance circuit 331 differently depending on which operation is performed among the read operation and the verification read operation.

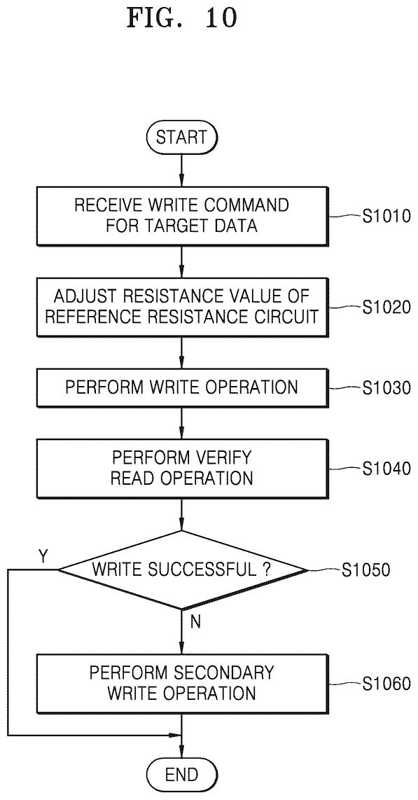

FIG. 10 is a flowchart illustrating a method of operating a memory device according to an example embodiment.

Referring to FIG. 10, in operation S1010, the memory device 300 may receive a write command for target data from the memory controller.

In operation S1020, the controller 320 of the memory device 300 may adjust the resistance value of the reference resistance circuit 331.

The controller 320 may adjust the resistance value of the reference resistance circuit 331 by generating and outputting a control signal for adjusting the resistance value of the reference resistance circuit 331 based on the value of the target data.

When the value of the target data is the first value, the controller may generate the control signal for adjusting the resistance value of the reference resistance circuit 331 to be the second reference resistance value R_{ref2}. When the value of the target data is the second value, the controller 320 may generate the control signal for adjusting the resistance value of the reference resistance circuit 331 to be the third reference resistance value R_{ref3}.

In operation S1030, the memory device 300 may perform a write operation for writing target data into the memory cell 310.

The memory device may write data into the memory cell by supplying a write current corresponding to the target data to the memory cell so that a resistance value of a variable resistance element included in the memory cell has a value corresponding to the target data.

In operation S1040, the memory device 300 may perform a verify read operation to determine whether target data is correctly written in the memory cell 310.

When the value of the target data is the first value, the memory device 300 may perform a verify read operation based on the second reference resistance value R_{ref2}. When the value of the target data is the second value, the memory device 300 may perform a verify read operation based on the third reference resistance value R_{ref3}.

In operation S1050, the memory device 300 may determine whether writing of the target data is successful.

When the data read in operation S1040 is the same as the target data, the memory device 300 may determine that writing of the target data has succeeded. When it is determined that writing of the target data is successful, an operation involved in receiving a writing command may be terminated.

Conversely, the memory device 300 may determine that writing of the target data has failed when the data read in operation S1040 is different from the target data. When it is determined that the writing of the target data has failed, it may move to operation S1060.

In operation S1060, the memory device 300 may perform the secondary write operation for writing target data to the memory cell 310. The secondary write operation may be performed in the same manner as the write operation of operation S1030.

After the secondary write operation is performed, an additional verify read operation may not be performed, and an operation involved in receiving a writing command may be terminated.

FIG. 10 shows an example embodiment in which up to the secondary write operation is performed when writing to target data fails, but the present disclosure is not limited thereto, and unlike FIG. 10, a third or higher write operation may be additionally performed.

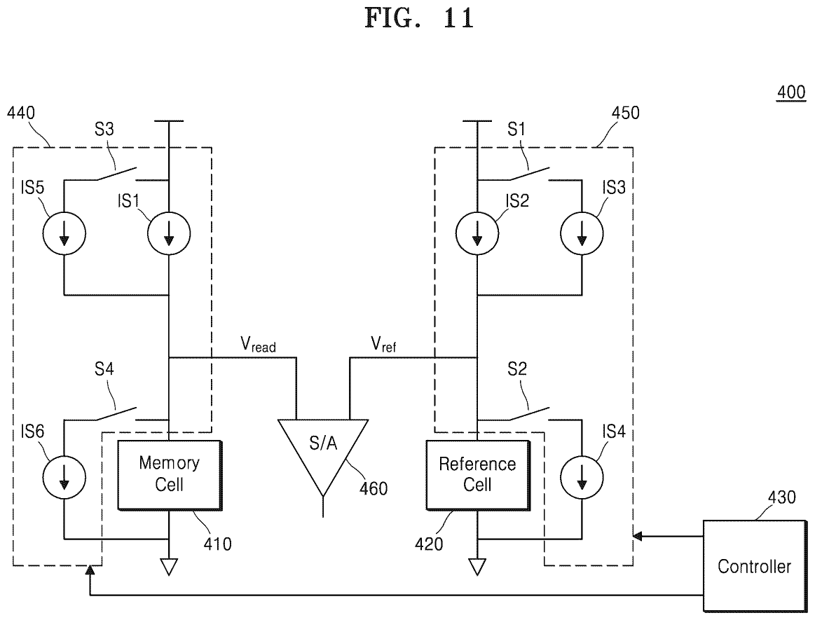

FIG. 11 is a circuit diagram illustrating a main configuration of a memory device according to another example embodiment.

Referring to FIG. 11, a memory device 400 according to another example embodiment may include a memory cell 410, a reference cell 420, a controller 430, a first current supply circuit 440, a second current supply circuit 450, and a sense amplifier 460. In this case, the memory device 400 of FIG. 11 may be implemented in the memory device 200 of FIG. 1 or 2.

The memory cell 410 may store data. The memory cell 410 may include a variable resistance element.

The variable resistance element may be in a P state or an AP state depending on values of written data. For example, when the value of the data written in the memory cell 410 is a first value, the variable resistance element may be in the P state. Conversely, when the value of the data written in the memory cell 410 is the second value, the variable resistance element may be in the AP state. In addition, when abnormal writing occurs in the memory cell 410, the variable resistance element may be temporarily in an intermediate state.

The reference cell 420 may include a reference resistance circuit. The reference resistance circuit may have a resistance value corresponding to the resistance value of the variable resistance element of the memory cell 410. In another example embodiment, a resistance value of the reference resistance circuit may have the first reference resistance value R_{ref1} and may not be changed by a control signal.

The controller 430 may generate a control signal based on which operation of the read operation and the verify read operation is performed by the memory device 400.

The controller 430 may generate a control signal for adjusting the states of the third and fourth switches S3 and S4 included in the first current supply circuit 440 to be described later, and the states of the first and second switches 51 and S2 included in the second current supply circuit 450.

The first current supply circuit 440 may apply a read current to the memory cell 410 based on the control signal.

The first current supply circuit 440 may include a first current source IS1. The first current source IS1 may apply a read current having a first current value to the memory cell 410.

The second current supply circuit 450 may apply a reference current to the reference cell 420 based on the control signal.

The second current supply circuit 450 may include a second current source IS2. The second current source IS2 may apply a reference current having a first current value to the reference cell 420. That is, the first current source IS1 and the second current source IS2 may supply current having the same current value.

The sense amplifier 460 may sense a difference between the read voltage value V_{read} applied from the memory cell 410 and the reference voltage value V_{ref} applied from the reference cell 420.

When the read voltage value V_{read} is less than the reference voltage value V_{ref}, the sense amplifier 460 may output a digital signal indicating that the value of the data written in the memory cell 410 is the first value. Conversely, when the read voltage value V_{read} is greater than the reference voltage value V_{ref}, the sense amplifier 460 may output a digital signal indicating that the value of the data written in the memory cell 410 is the second value.

In some example embodiments, the second current supply circuit 450 may further include a third current source IS3, a first switch 51, a fourth current source IS4, and a second switch S2.

The third current source IS3 may be connected in parallel with the second current source IS2. The third current source IS3 may selectively increase the reference current by the second current value.

The first switch 51 may adjust the connection between the second current source IS2 and the third current source IS3 based on the control signal.

The first switch 51 is turned on by a control signal to connect the second current source IS2 to the third current source IS3. In this case, the third current source IS3 may increase the reference current by the second current value.

In addition, the first switch 51 may be turned off by a control signal to open between the second current source IS2 and the third current source IS3. In this case, because the third current source IS3 is not connected to the second current source IS2, the third current source IS3 may not operate.

The fourth current source IS4 may be connected in parallel with the reference cell 420. The fourth current source IS4 may selectively reduce the reference current by a third current value.

The second switch S2 may adjust the connection between the reference cell 420 and the fourth current source IS4 based on the control signal.

The second switch S2 is turned on by the control signal to connect the reference cell 420 to the fourth current source IS4. In this case, the fourth current source IS4 may reduce the reference current by the third current value.

In addition, the second switch S2 may be turned off by a control signal to open a connection between the reference cell 420 and the fourth current source IS4. In this case, because the fourth current source IS4 is not connected to the reference cell 420, the fourth current source IS4 may not operate.

Current values flowing through each of the first current source IS1, the second current source IS2, the third current source IS3, and the fourth current source IS4 may be set based on the resistance distribution of the variable resistance element of the memory cell 410.

In some example embodiments, the first current value, which is the current value flowing through the first current source IS1 and the second current source IS2, may be proportional to the first reference resistance value R_{ref1}, the second current value, which is the current value flowing through the third current source IS3, may be proportional to a value obtained by subtracting the first reference resistance value R_{ef1} from the third reference resistance value R_{ref3}, and the third current value, which is the current value flowing through the fourth current source IS4, may be proportional to a value obtained by subtracting the second reference resistance value R_{ref2} from the first reference resistance value R_{ref1}.

In this way, as the first current value, the second current value, and the third current value are set, by adjusting the current value applied to the reference cell 420, the same read voltage value V rea d and reference voltage value V_{ref} as when the resistance value of the reference resistance circuit 331 is changed in the embodiments of FIGS. 5 to 10 may be provided to the sense amplifier 460.

When the memory device 400 performs the read operation, the controller 430 may generate a control signal for controlling the first switch 51 and the second switch S2 to be turned off. Accordingly, the third current source IS3 and the fourth current source IS4 may not operate. Therefore, the read current having a first current value may be applied to the memory cell 410, and the reference current having a first current value may be applied to the reference cell 420.

When the value of the target data is the first value when the memory device 400 performs the verify read operation, the controller 430 may generate a control signal for controlling the first switch 51 to turn off and the second switch S2 to turn on. Accordingly, the third current source IS3 may not operate, and the fourth current source IS4 may operate. Accordingly, a read current having a first current value may be applied to the memory cell 410, and a reference current having a value obtained by subtracting the third current value from the first current value may be applied to the reference cell 420. In this case, because the reference voltage value V_{ref} is proportional to the resistance value of the reference resistance circuit and the reference current value, by reducing the reference current as described above, the same read voltage value V_{read} and the reference voltage value V_{ref} as when the resistance value of the reference resistance circuit 331 is reduced in the example embodiments of FIGS. 5 to 10 may be provided to the sense amplifier 460.

When the value of the target data is the second value when the memory device 400 performs the verify read operation, the controller 430 may generate a control signal for controlling the first switch 51 to turn on and the second switch S2 to turn off. Accordingly, the third current source IS3 may operate, and the fourth current source IS4 may not operate. Therefore, a read current having a first current value may be applied to the memory cell 410, and a reference current having a value obtained by adding the second current value to the first current value may be applied to the reference cell 420. In this case, because the reference voltage value V_{ref} is proportional to the resistance value of the reference resistance circuit and the reference current value, by increasing the reference current as described above, the same read voltage value V_{read} and the reference voltage value V_{ref} as when the resistance value of the reference resistance circuit 331 is increased in the example embodiments of FIGS. 5 to 10 may be provided to the sense amplifier 460.

In the second example of another example embodiment, the first current supply circuit 440 may further include a fifth current source IS5, a third switch S3, a sixth current source IS6, and a fourth switch S4.

The fifth current source IS5 may be connected in parallel with the first current source IS1. The fifth current source IS5 may selectively increase the read current by the second current value.

The third switch S3 may adjust the connection between the first current source IS1 and the fifth current source IS5 based on the control signal.

The third switch S3 is turned on by the control signal to connect the first current source IS1 to the fifth current source IS5. In this case, the fifth current source IS5 may increase the reference current by a second current value.

In addition, the third switch S3 may be turned off by a control signal to open the first current source IS1 and the fifth current source IS5. In this case, because the fifth current source IS5 is not connected to the first current source IS1, the fifth current source IS5 may not operate.

The sixth current source IS6 may be connected in parallel with the memory cell 410. The sixth current source IS6 may selectively reduce the read current by a third current value.

The fourth switch S4 may adjust the connection between the memory cell 410 and the sixth current source IS6 based on the control signal.

The fourth switch S4 is turned on by the control signal to connect the reference cell 420 to the sixth current source IS6. In this case, the sixth current source IS6 may decrease the reference current by a third current value.

In addition, the fourth switch S4 may be turned off by a control signal to open a connection between the reference cell 420 and the sixth current source IS6. In this case, because the sixth current source IS6 is not connected to the reference cell 420, the sixth current source IS6 may not operate.

The first current value that is a current value flowing through the first current source IS1 and the second current source IS2, the second current value that is a current value flowing through the fifth current source IS5, and the third current value that is a current value flowing through the sixth current source IS6 may be set based on the distribution of resistance values of the variable resistance element of the memory cell 410 and may be set in the same manner as described above.

When the memory device 400 performs a read operation, the controller 430 may generate a control signal for controlling the third switch S3 and the fourth switch S4 to be turned off. Accordingly, the fifth current source IS5 and the sixth current source IS6 may not operate. Therefore, a read current having a first current value may be applied to the memory cell 410, and a reference current having a first current value may be applied to the reference cell 420.

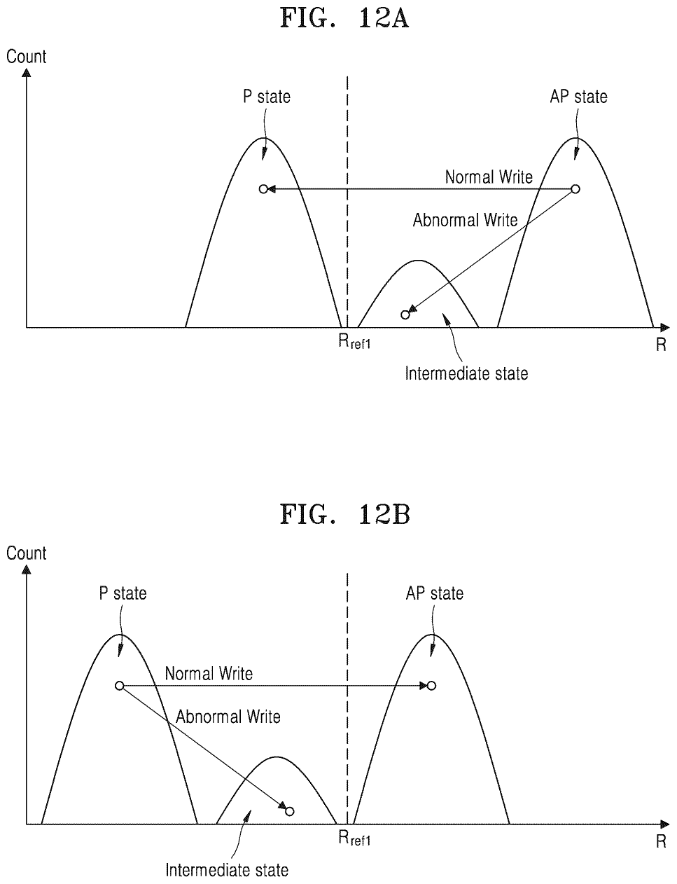

When the value of the target data is the first value when the memory device 400 performs the verify read operation, the controller 430 may generate a control signal for controlling the third switch S3 to turn on and the fourth switch S4 to turn off. Accordingly, the fifth current source IS5 may operate, and the sixth current source IS6 may not operate. Accordingly, a read current having a value obtained by adding the second current value to the first current value may be applied to the memory cell 410, and a reference current having the first current value may be applied to the reference cell 420. In this case, because the read voltage value V_{read} is proportional to the resistance value and the read current value of the variable resistance element, by increasing the read current as described above, the read voltage value V_{read} may be increased in the same way as the resistance value of the variable resistance element is increased. Therefore, as shown in FIG. 12A, the same result as when the resistance value distribution of the variable resistance element moves in the direction of increasing may be obtained.

When the value of the target data is the second value when the memory device 400 performs the verify read operation, the controller 430 may generate a control signal for controlling the third switch S3 to turn off and the fourth switch S4 to turn on. Accordingly, the fifth current source IS5 may not operate, and the sixth current source IS6 may operate. Accordingly, a read current having a value obtained by subtracting the third current value from the first current value may be applied to the memory cell 410, and a reference current having the first current value may be applied to the reference cell 420. In this case, because the read voltage value V_{read} is proportional to the resistance value and the read current value of the variable resistance element, by decreasing the read current as described above, the read voltage value V_{read} may be decreased in the same way as the resistance value of the variable resistance element is decreased. Therefore, as shown in FIG. 12B, the same result as when the resistance value distribution of the variable resistance element moves in the direction of decreasing may be obtained.

In some example embodiments, the first current supply circuit 440 may further include a fifth current source IS5 and a third switch S3 and the second current supply circuit 450 may further include a third current source IS3 and a first switch 51.

Connection and control of the fifth current source IS5, the third switch S3, the third current source IS3, and the first switch 51 may be the same as those described above in the first and second examples.

When the memory device 400 performs a read operation, the first switch 51 and the third switch S3 may be turned off.

When the value of the target data is the first value when the memory device 400 performs the verify read operation, the first switch 51 may be turned off and the third switch S3 may be turned on. Accordingly, a read current having a value obtained by adding a second current value to a first current value may be applied to the memory cell 410, and a reference current having a first current value may be applied to the reference cell 420. Therefore, as shown in FIG. 12A, the same result as when the resistance value distribution of the variable resistance element moves in the direction of increasing may be obtained.

When the value of the target data is the second value when the memory device 400 performs the verify read operation, the first switch 51 may be turned on and the third switch S3 may be turned off. Accordingly, a read current having a first current value may be applied to the memory cell 410, and a reference current having a value obtained by adding the second current value to the first current value may be applied to the reference cell 420. Therefore, in the example embodiments of FIGS. 5 to 10, the same read voltage value V_{read} and reference voltage value V_{ref} as when the resistance value of the reference resistance circuit 331 is increased may be provided to the sense amplifier 460.

In some example embodiments, the first current supply circuit 440 may further include a sixth current source IS6 and a fourth switch S4 and the second current supply circuit 450 may further include a fourth current source IS4 and a second switch S2.

Connection and control of the sixth current source IS6, the fourth switch S4, the fourth current source IS4, and the second switch S2 may be the same as those described above in the first and second examples.

When the memory device 400 performs a read operation, the second switch S2 and the fourth switch S4 may be turned off.

When the value of the target data is the first value when the memory device 400 performs the verify read operation, the second switch S2 may be turned on and the fourth switch S4 may be turned off. Accordingly, a read current having a first current value may be applied to the memory cell 410, and a reference current having a value obtained by subtracting the third current value from the first current value may be applied to the reference cell 420. Therefore, in the example embodiments of FIGS. 5 to 10, the same read voltage value V_{read} and reference voltage value V_{ref} as when the resistance value of the reference resistance circuit 331 is reduced may be provided to the sense amplifier 460.

When the memory device 400 performs the verify read operation and the value of the target data is the second value, the second switch S2 may be turned off and the fourth switch S4 may be turned on. Accordingly, a read current having a value obtained by subtracting the third current value from the first current value may be applied to the memory cell 410, and a reference current having a first current value may be applied to the reference cell 420. Therefore, as shown in FIG. 12B, the same result as when the resistance value distribution of the variable resistance element moves in the direction of decreasing may be obtained.

FIGS. 12A and 12B are graphs illustrating changes in distribution of resistance values of variable resistance elements in a memory device according to an example embodiment.

Referring to FIG. 12A, when the memory device 400 performs the verify read operation, in a case where the third switch S3 is turned on and a read current having a value obtained by adding the first current value and the second current value is applied to the memory cell 410, the distribution of resistance values of the variable resistance element may be confirmed. In the example embodiment of FIG. 12A, it may be seen that the distribution of resistance values of the variable resistance element shifts in a direction of increase compared to the resistance value of the variable resistance element shown in the example embodiment of FIG. 4. In this case, in the resistance value distribution of the variable resistance element, a maximum value of resistance that the variable resistance element may have when it is in the P state may be less than the first reference resistance value R_{ref1}, and a minimum value of resistance that the variable resistance element may have when it is in the intermediate state may be greater than the first reference resistance value R_{ref1}. In this case, the resistance value distribution of the variable resistance element does not actually shift, but the same result as shifting as shown in FIG. 12A may occur.

The graph of FIG. 12A shows an example of a state change of the variable resistance element when the memory device 400 writes a first value into the memory cell 410 storing the second value.

When the first value is normally written into the memory cell 410 in which the second value is stored, the state of the variable resistance element may be immediately converted from the AP state to the P state.

However, when the first value is abnormally written into the memory cell 410 in which the second value is stored, the state of the variable resistance element may be converted from the AP state to an intermediate state. In this case, the memory device 400 may determine a value of data written in the memory cell 410 based on the first reference resistance value R_{ref1}. In this case, in the example embodiment of FIG. 12A, because the distribution of resistance values of the variable resistance element moves in the direction of increasing, the minimum resistance value that the variable resistance element may have when it is in an intermediate state becomes greater than the first reference resistance value R_{ref1}, and thus the sense amplifier 340 may output a digital signal indicating that the value of the written data is the second value when the variable resistance element is in an intermediate state. In this case, because the value of the target data is different from the value of the data read through the verify read operation, the memory device 300 may determine that the write operation has been performed abnormally.

Accordingly, when the state of the variable resistance element is an intermediate state, it is determined that the write operation has been performed abnormally regardless of which state of the variable resistance element is switched from the intermediate state to the P state or the AP state, and thus all data miswrites may be detected through the verify read operation.

Referring to FIG. 12B, when the memory device 400 performs the verify read operation, in a case where the fourth switch S4 is turned on and a read current having a value obtained by subtracting the third current value from the first current value is applied to the memory cell 410, the distribution of resistance values of the variable resistance element may be confirmed. In the example embodiment of FIG. 12B, it may be seen that the distribution of resistance values of the variable resistance element shifts in a direction of decrease compared to the resistance value of the variable resistance element shown in the example embodiment of FIG. 4. In this case, in the resistance value distribution of the variable resistance element, a maximum value of resistance that the variable resistance element may have when it is in the intermediate state may be less than the first reference resistance value R_{ref1}, and a minimum value of resistance that the variable resistance element may have when it is in the AP state may be greater than the first reference resistance value R_{ref1}. In this case, the resistance value distribution of the variable resistance element does not actually shift, but the same result as shifting as shown in FIG. 12B may occur.

The graph of FIG. 12B shows an example of a state change of the variable resistance element when the memory device 400 writes a second value into the memory cell 410 storing the first value.

When the second value is normally written into the memory cell 410 in which the first value is stored, the state of the variable resistance element may be immediately converted from the P state to the AP state.

However, when the second value is abnormally written into the memory cell 410 in which the first value is stored, the state of the variable resistance element may be converted from the P state to an intermediate state. In this case, the memory device 400 may determine a value of data written in the memory cell 410 based on the first reference resistance value R_{ref1}. In this case, in the example embodiment of FIG. 12B, because the distribution of resistance values of the variable resistance element moves in the direction of decreasing, the maximum resistance value that the variable resistance element may have when it is in an intermediate state becomes less than the first reference resistance value R_{ref1}, and thus the sense amplifier 340 may output a digital signal indicating that the value of the written data is the first value when the variable resistance element is in an intermediate state. In this case, because the value of the target data is different from the value of the data read through the verify read operation, the memory device 300 may determine that the write operation has been performed abnormally.

Accordingly, when the state of the variable resistance element is an intermediate state, it is determined that the write operation has been performed abnormally regardless of which state of the variable resistance element is switched from the intermediate state to the P state or the AP state, and thus all data miswrites may be detected through the verify read operation.

When the memory device 300 according to the example embodiments as described above with reference to FIGS. 11 and 12 is used, it is possible to accurately verify whether data is written incorrectly by adjusting the read current or the reference current depending on which operation is performed among the read operation and the verification read operation.

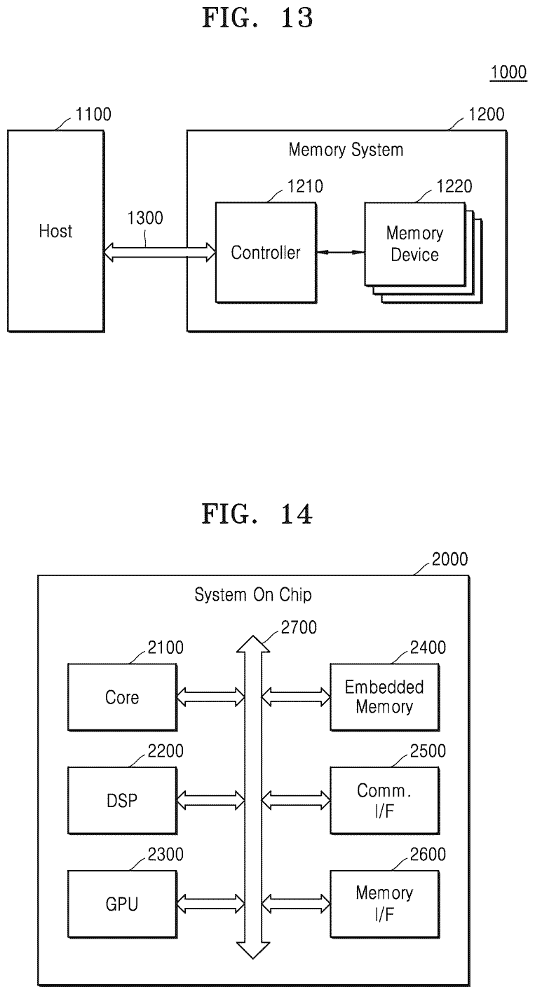

FIG. 13 is a block diagram illustrating a memory system including a memory device according to an example embodiment.

Referring to FIG. 13, a memory system 1200 may communicate with a host 1100 and may include a controller 1210 and a memory device 1220.

An interface 1300 through which the memory system 1200 communicates with the host 1100 may use an electrical signal and/or an optical signal through wired or wireless, and may be implemented, as non-limiting examples, as a serial advanced technology attachment (SATA) interface, a SATA express (SATAe) interface, a serial attached small computer system interface (SAS), a peripheral component interconnect express (PCIe) interface, a non-volatile memory express (NVMe) interface, an advanced host controller interface (AHCI), or a combination thereof.

In some example embodiments, the memory system 1200 may communicate with the host 1100 by being removably coupled to the host 1100. As a resistive memory, the memory device 1220 may be a non-volatile memory, and the memory system 1200 may also be referred to as a storage system. For example, the memory system 1200 may be implemented, as non-limiting examples, as a solid-state drive or solid-state disk (SSD), an embedded SSD (eSSD), a multimedia card (MMC), an embedded multimedia card (eMMC), or the like.

The controller 1210 may control the memory device 1220 in response to a request received from the host 1100 through the interface 1300. For example, the controller 1210 may write data received along with the write request into the memory device 1220 in response to the write request, and may provide data stored in the memory device 1220 to the host 1100 in response to a read request.

The memory system 1200 may include at least one memory device 1220. The memory device 1220 may be implemented as the memory device 300 like the example embodiment shown in FIG. 5 or as the memory device 400 like the example embodiment shown in FIG. 11.

FIG. 14 is a block diagram illustrating a system-on-chip including a memory device according to an example embodiment.

Referring to FIG. 14, a system on chip (SoC) 2000 may include a core 2100, a Digital Signal Processor (DSP) 2200, a graphics processing unit (GPU) 2300, a built-in (e.g., embedded) memory 2400, and a communication interface 2500, and a memory interface 2600. Components of the SoC 2000 may communicate with each other through a bus 2700.

The SoC 2000 may refer to an integrated circuit that integrates components of a computing system or other electronic system. For example, an application processor (AP) as one of the SoCs 2000 may include a processor and components for other functions.

The core 2100 may process instructions and control operations of components included in the SoC 2000. For example, the core 2100 may drive an operating system and execute applications on the operating system by processing a series of commands. The DSP 2200 may generate useful data by processing digital signals, for example, digital signals provided from the communication interface 2500. The GPU 2300 may generate data for an image output through a display device from image data provided from the built-in memory 2400 or the memory interface 2600, or may encode the image data. The communication interface 2500 may provide an interface for a communication network or one-to-one communication. The memory interface 2600 may provide an interface to an external memory of the SoC 2000, such as dynamic random access memory (DRAM) or flash memory.

The built-in memory 2400 may store data for the operation of the core 2100, the DSP 2200, and the GPU 2300. The built-in memory 2400 may include a memory device 300 like the example embodiment shown in FIG. 5 or a memory device 400 like the example embodiment shown in FIG. 11.

Any functional blocks shown in the figures and described above may be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various changes in form and details may be made therein without departing from the spirit and scope of the following claims.

What is claimed is:

1. A memory device comprising:
a memory cell including a variable resistance element;
a controller configured to generate a control signal based on whether the memory device performs a read operation or a verify read operation;
a reference cell including a reference resistance circuit configured to have different resistance values depending on the control signal; and
a sense amplifier configured to sense a difference between a read voltage value applied from the memory cell and a reference voltage value applied from the reference resistance circuit.

2. The memory device of claim 1, wherein the controller is configured to generate the control signal based on a target data value when the memory device performs the verify read operation.

3. The memory device of claim 2, wherein the reference resistance circuit,
when the memory device performs the verify read operation and the target data value is a first value, is configured to have a first reference resistance value less than a specific reference resistance value, the specific reference resistance value being a resistance value of the reference resistance circuit when the memory device performs the read operation, and
when the memory device performs the verify read operation the target data value is a second value, is configured to have a second reference resistance value greater than the specific reference resistance value.

4. The memory device of claim 1, wherein the reference resistance circuit includes a plurality of resistance elements and a plurality of switching elements, and
the reference resistance circuit is configured to change a resistance value thereof as the plurality of switching elements are turned on or off by the control signal.

5. The memory device of claim 1, wherein the reference resistance circuit comprises:
a first resistance element configured to be connected to the sense amplifier;
a second resistance element configured to be connected in series with the first resistance element;
a third resistance element connected in series with the second resistance element;
a first switching element configured to be turned on or off by the control signal and to be connected in parallel to the second resistance element and the third resistance element; and
a second switching element configured to be turned on or off by the control signal and connected in parallel with the third resistance element.

6. The memory device of claim 5, wherein the controller is configured to generate the control signal for controlling the first switching element to be turned off and the second switching element to be turned on when the memory device performs the read operation.

7. The memory device of claim 5, wherein the controller is configured to generate the control signal for controlling both the first switching element and the second switching element to be turned on or both the first switching element and the second switching element to be turned off when the memory device performs the verify read operation.

8. The memory device of claim 7, wherein the controller is configured to,
generate the control signal for controlling both the first switching element and the second switching element to be turned on when the memory device performs the verify read operation and a target data value is a first value, and
generate the control signal for controlling both the first switching element and the second switching element to be turned off when the memory device performs the verify read operation and the target data value is a second value.

9. The memory device of claim 5, wherein a resistance value of each of the first resistance element, the second resistance element, and the third resistance element is set based on a distribution of resistance values of the variable resistance element.

10. The memory device of claim 5, wherein the reference resistance circuit further includes a distribution circuit configured to generate a first signal input to the first switching element and a second signal input to the second switching element based on the control signal.

11. A method of operating a memory device for writing data into a memory cell including a variable resistance element, the method comprising:
receiving a write command for target data from a memory controller;
generating and outputting a control signal for adjusting a resistance value of a reference resistance circuit based on the target data;
writing the target data to the memory cell; and
performing a verify read operation on the memory cell based on a read voltage value applied from the memory cell and a reference voltage value applied from the reference resistance circuit.

12. The method of claim 11, wherein the generating includes:
when a target data value is a first value, generating the control signal controlling a first reference resistance value to have a value less than a specific reference resistance value that is a resistance value of the reference resistance circuit when the memory device performs a read operation; and
when the target data value is a second value, generating the control signal controlling the resistance value of the reference resistance circuit to have a second reference resistance value higher than the specific reference resistance value.

13. The method of claim 11, further comprising:
determining whether the target data is normally written to the memory cell after performing the verify read operation; and
rewriting the target data into the memory cell when a result of the determining indicating that the target data is not normally written.

14. A memory device comprising:
a memory cell including a variable resistance element;
a reference cell including a reference resistance circuit having a reference resistance value corresponding to a resistance value of the variable resistance element;
a controller configured to generate a control signal based on whether the memory device performs a read operation or a verify read operation;
a first current supply circuit including a first current source and configured to apply a read current to the memory cell based on the control signal;
a second current supply circuit including a second current source and configured to apply a reference current to the reference resistance circuit based on the control signal; and
a sense amplifier configured to sense a difference between a read voltage value applied from the memory cell and a reference voltage value applied from the reference resistance circuit.

15. The memory device of claim 14, wherein the second current supply circuit comprises:
a third current source connected in parallel with the second current source and selectively increasing the reference current;
a first switch adjusting a first connection between the second current source and the third current source based on the control signal;
a fourth current source connected in parallel with the reference cell and selectively reducing the reference current; and
a second switch adjusting a second connection between the reference cell and the fourth current source based on the control signal.

16. The memory device of claim 15, wherein a current value flowing through each of the first current source, the second current source, the third current source, and the fourth current source is set based on a distribution of resistance values of the variable resistance element.

17. The memory device of claim 14, wherein the first current supply circuit comprises:
a fifth current source connected in parallel with the first current source and selectively increasing the read current;
a third switch adjusting a first connection between the first current source and the fifth current source based on the control signal;
a sixth current source connected in parallel with the memory cell and selectively reducing the read current; and
a fourth switch adjusting a second connection between the memory cell and the sixth current source based on the control signal.

18. The memory device of claim 17, wherein a current value flowing through each of the first current source, the second current source, the fifth current source, and the sixth current source is set based on a distribution of resistance values of the variable resistance element.

19. The memory device of claim 14,
wherein the first current supply circuit comprises:
a fifth current source connected in parallel with the first current source and selectively increasing the read current; and
a third switch adjusting a first connection between the first current source and the fifth current source based on the control signal, and
the second current supply circuit comprises:
a third current source connected in parallel with the second current source and selectively increasing the reference current; and
a first switch adjusting a second connection between the second current source and the third current source based on the control signal.

20. The memory device of claim 14,
wherein the first current supply circuit comprises:
a sixth current source connected in parallel with the memory cell and selectively reducing the read current; and
a fourth switch adjusting a connection between the memory cell and the sixth current source based on the control signal, and
the second current supply circuit comprises:
a fourth current source connected in parallel with the reference cell and selectively reducing the reference current; and
a second switch adjusting the connection between the reference cell and the fourth current source based on the control signal.
